(19) United States
(12) Patent Application Publication
(10) Pub. No.: US 2007/0072352 A1
(43) Pub. Date: Mar. 29, 2007

(54) Insulated gate field effect transistor and manufacturing method thereof

(75) Inventors: Kazunari Kushiyama, Gunma (JP); Tetsuya Okada, Saitama (JP); Makoto Oikawa, Gunma (JP); Hiroyasu Ishida, Gunma (JP); Yasuyuki Sayama, Gunma (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/519,208

(22) Filed: Sep. 12, 2006

(30) Foreign Application Priority Data
Sep. 29, 2005 (JP) 2005-284110

(51) Int. Cl. H01L 21/337; H01L 21/8242; H01L 21/336

(52) U.S. Cl. 438/186; 438/268; 438/242

(57) ABSTRACT

A separation hole is provided in the center of the gate electrode. Accordingly, it is possible to suppress a drastic increase in feedback capacitance Crss in the case where drain-source voltage VDS is decreased and the width of the depletion layer is narrowed. Thus, high-frequency switching characteristics are improved. Moreover, n type impurities are implanted from the separation hole to form an n type impurity region between channel regions. Since a resistance in a portion below the gate electrode can be reduced, an on-resistance can be reduced. The n type impurity region can be formed in a self-aligning manner.

### BACKGROUND OF THE INVENTION

Priority is claimed to Japanese Patent Application Number JP2005-284110 filed on Sep. 29, 2005, the disclosure of which is incorporated herein by reference in its entirety.

1. Field of the Invention

The present invention relates to an insulated gate field effect transistor and a manufacturing method thereof. More particularly, the present invention relates to an insulated gate field effect transistor, which realizes reduction in feedback capacitance, and a manufacturing method thereof.

2. Description of the Related Art

With reference to FIG. 16, an n-channel MOSFET will be described as an example of a conventional insulated gate field effect transistor.

As shown in FIG. 16, a drain region 22 is provided by superposing an n⁻ type semiconductor layer on an n⁺ type silicon semiconductor substrate 21. In a surface of the drain region 22, a plurality of p type channel regions 24 are provided. On a surface of the n⁻ type semiconductor layer 22 between the adjacent channel regions 24, a gate electrode 33 is provided with a gate insulating film 31 interposed in between. The gate electrode 33 is covered with an interlayer insulating film 36 on a periphery thereof. Moreover, in a surface of the channel region 24, n⁺ type source regions 35 are provided. In the surface of the channel region 24 between the source regions 35, p⁺ type body region 37 is provided. The source regions 35 and the body region 37 are in contact with a source electrode 38. This technology is described for instance in Japanese Patent Application Publication No. Hei 5 (1993)-121747.

The MOSFET shown in FIG. 16 is a so-called planar vertical MOSFET in which gate electrodes are provided on a surface of a substrate.

FIGS. 17 and 18 show a state of a MOSFET at the time of switching. FIG. 17A is a graph showing a relationship between gate-source voltage VGS and total charge Qg of a gate. FIG. 17B is a graph showing a relationship between drain-source voltage VDS and feedback capacitance Crss (gate-drain capacitance Cgd). FIG. 18 is a cross-sectional view at the time of switching of the MOSFET.

With reference to FIG. 17A, when the gate-source voltage VGS is applied in a state where certain drain-source voltage VDS (not shown) is applied, gate-source charge Qgs (the total charge Qg) is increased along with an increase in the gate-source voltage VGS. Thereafter, when the gate-source voltage VGS gets close to pinch-off voltage Vp of the gate, the MOSFET is turned on and the drain-source voltage VDS is decreased. Meanwhile, the gate-source voltage VGS is not increased, and gate-drain charge Qgd (total charge Qg) is accumulated. Thereafter, along with an increase in the gate-source voltage VGS, the total charge Qg is increased again.

Moreover, as shown in FIG. 17B, along with a decrease in the drain-source voltage VDS, the feedback capacitance Crss is increased. Specifically, when the MOSFET is turned on and the drain-source voltage VDS falls below certain voltage (for example, about 10 V in FIG. 17B), the feedback capacitance Crss is drastically increased.

FIG. 18 is a cross-sectional view showing the state described above.

Along with a decrease in the drain-source voltage VDS, a width of a depletion layer 50, which has been extended from the channel regions 24, is reduced as indicated by arrows. In the region where the depletion layer 50 is extended, depletion capacitance C1 is generated. Moreover, between the substrate surface and the gate electrode 33 as well as a gate oxide film 31, gate oxide film capacitance C2 is generated.

Here, the feedback capacitance Crss (the gate-drain capacitance Cgd) which affects high-frequency switching characteristics is a sum of the depletion capacitance C1 and the gate oxide film capacitance C2. In order to improve the high-frequency switching characteristics, the feedback capacitance Crss is preferably as low as possible.

As to the depletion capacitance C1, since a distance d1 in a gate-drain direction is large and an area S is small, a capacitance value is small. Meanwhile, in a region where the depletion layer 50 has disappeared (around a center of the gate electrode 33), only the gate oxide film capacitance C2 is present. Moreover, since the gate oxide film capacitance C2 has a small thickness (distance d2), the capacitance becomes very large. Specifically, in the planar MOSFET, along with a decrease in the drain-source voltage VDS, the feedback capacitance Crss particularly around the center of the gate electrode 33 is drastically increased. Thus, characteristics as shown in FIG. 17B are obtained.

Total quantity of the feedback capacitance Crss until the drain-source voltage VDS becomes ON voltage after the feedback capacitance Crss is drastically increased, in other words, an integration value of a region x indicated by hatching, becomes the gate-drain charge Qgd shown in FIG. 17A.

The gate-drain charge Qgd means quantity of charge accumulated between the gate and the drain when the MOSFET is in the ON state (when the drain-source voltage VDS decreases). At the time of switching, the MOSFET is turned off once the charge is released. Thus, when the gate-drain charge Qgd is large, a switching speed is reduced. Specifically, in order to improve the high-frequency switching characteristics, it is desirable that the integration value of the region x be small.

However, the integration value of the region x is determined by the drain-source voltage VDS applied to the MOSFET in the ON state as shown in FIG. 17B. Thus, there has been a limitation on improvement of the high-frequency switching characteristics.

### SUMMARY OF THE INVENTION

The present invention provides an insulated gate field effect transistor that includes a semiconductor substrate of a first general conductivity type, a semiconductor layer of the first general conductivity type disposed on the semiconductor substrate so as to provide a drain region, a first channel region, a second channel region, a third channel region and a fourth channel region that are of a second general conductivity type and formed in the semiconductor layer, a first gate electrode disposed on the first and second channel regions and having a separation separating a first part of the first gate electrode from a second part of the first gate electrode, a second gate electrode disposed on the third and fourth channel regions and having a separation separating a first part of the second gate electrode from a second part of the second gate electrode, a body region of the second general conductivity type formed in the semiconductor layer and connecting the second and third channel regions, and a source region of the first general conductivity type formed in each of the channel regions.

The present invention also provides a method of manufacturing an insulated gate field effect transistor. The method includes providing a device intermediate comprising a semiconductor substrate of a first general conductivity type, a semiconductor layer of the first general conductivity type disposed on the semiconductor substrate and an insulating film disposed on the semiconductor layer, forming a first gate electrode on the insulating film having a separation so that the insulating film is exposed at a bottom of the separation of the first gate electrode, forming a second gate electrode on the insulating film having a separation so that the insulating film is exposed at a bottom of the separation of the second gate electrode, forming an impurity region of a second general conductivity type in the semiconductor layer between the first and second gate electrodes, forming a first source region of the first general conductivity type in the impurity region adjacent the first gate electrode, forming a second source region of the first general conductivity type in the impurity region adjacent the second gate electrode, and forming a body region of the second general conductivity type in the impurity region between the first and second source regions.

The present invention further provides a method of manufacturing an insulated gate field effect transistor, comprising. The method includes providing a device intermediate comprising a semiconductor substrate of a first general conductivity type, a semiconductor layer of the first general conductivity type disposed on the semiconductor substrate and a first insulating film disposed on the semiconductor layer, forming a gate electrode on the first insulating film having a separation so that the first insulating film is exposed at a bottom of the separation, forming a second insulting film on the gate electrode to fill the separation, the second insulating film containing impurity ions of the first general conductivity type, forming an impurity region of the first general conductivity type under the separation by diffusing the impurity ions from the second insulating film, and forming a source region of the first general conductivity type in the semiconductor layer adjacent the gate electrode.

The present invention further provides a method of manufacturing an insulated gate field effect transistor. The method includes providing a device intermediate comprising a semiconductor substrate of a first general conductivity type, a semiconductor layer of the first general conductivity type disposed on the semiconductor substrate and an insulating film disposed on the semiconductor layer, forming a first gate electrode on the insulating film having a separation so that the insulating film is exposed at a bottom of the separation of the first gate electrode, forming a second gate electrode on the insulating film having a separation so that the insulating film is exposed at a bottom of the separation of the second gate electrode, forming an impurity region of a second general conductivity type in the semiconductor layer between the first and second gate electrodes, forming a first source region of the first general conductivity type in the impurity region adjacent the first gate electrode, forming a second source region of the first general conductivity type in the impurity region adjacent the second gate electrode, and forming a trench in the impurity region between the first and second source regions.

### BRIEF DESCRIPTION OF THE DRAWINGS

FIG. 1A is a cross-sectional view and FIG. 1B is a perspective view for explaining an insulated gate field effect transistor of a first embodiment of the present invention.

FIG. 2A is another cross-sectional view and FIG. 2B is a characteristic graph for explaining the insulated gate field effect transistor of the first embodiment of the present invention.

FIG. 3 is a cross-sectional view for explaining an insulated gate field effect transistor of a second embodiment of the present invention.

FIG. 4A is a cross-sectional view and FIG. 4B is a characteristic graph for explaining an insulated gate field effect transistor of a third embodiment of the present invention.

FIG. 5 is a cross-sectional view for explaining an insulated gate field effect transistor of a forth embodiment of the present invention.

FIG. 6 is a cross-sectional view for explaining a method of manufacturing an insulated gate field effect transistor of the second embodiment of the present invention.

FIGS. 7A and 7B are cross-sectional views for explaining the method of manufacturing an insulated gate field effect transistor of the second embodiment of the present invention.

FIGS. 8A to 8C are cross-sectional views for explaining the method of manufacturing an insulated gate field effect transistor of the second embodiment of the present invention.

FIGS. 9A and 9B are cross-sectional views for explaining the method of manufacturing an insulated gate field effect transistor of the second embodiment of the present invention.

FIGS. 10A to 10C are cross-sectional views for explaining the method of manufacturing an insulated gate field effect transistor of the second embodiment of the present invention.

FIG. 11 is a cross-sectional view for explaining the method of manufacturing an insulated gate field effect transistor of the second embodiment of the present invention.

FIGS. 12A and 12B are cross-sectional views for explaining the method of manufacturing an insulated gate field effect transistor of the forth embodiment of the present invention.

FIG. 13 is a cross-sectional view for explaining the method of manufacturing an insulated gate field effect transistor of the forth embodiment of the present invention.

FIGS. 14A to 14C are cross-sectional views for explaining the method of manufacturing an insulated gate field effect transistor of the forth embodiment of the present invention.

FIG. 15 is a cross-sectional view for explaining the method of manufacturing an insulated gate field effect transistor of the forth embodiment of the present invention.

FIG. 16 is a cross-sectional view for explaining a conventional insulated gate field effect transistor.

FIGS. 17A and 17B are characteristic graphs for explaining the conventional insulated gate field effect transistor.

FIG. 18 is a cross-sectional view for explaining the conventional insulated gate field effect transistor.

### DESCRIPTION OF THE EMBODIMENTS

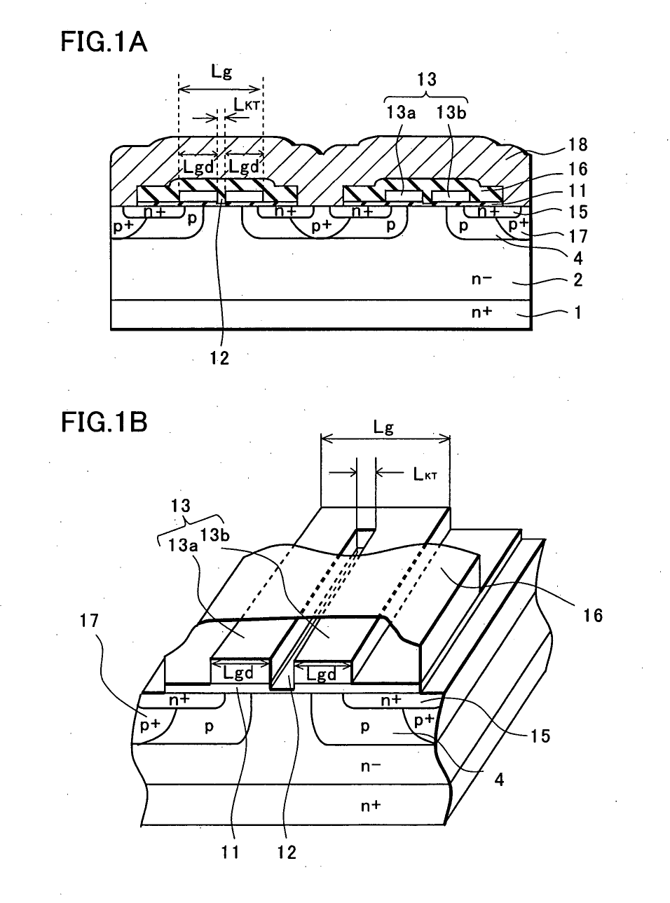

With reference to FIGS. 1 to 15, embodiments of the present invention will be described by taking an n-channel MOSFET as an example.

FIGS. 1A and 1B are views showing a structure of a MOSFET according to a first embodiment. FIG. 1A is a cross-sectional view and FIG. 1B is a perspective view.

The MOSFET includes a semiconductor substrate 1, a semiconductor layer 2, a channel region 4, a gate electrode 13, a separation hole 12, a gate insulating film 11, an interlayer insulating film 16, a source region 15 and a body region 17.

A drain region is provided by superposing, for example, an n⁻ type epitaxial layer 2 on an n⁺ type silicon semiconductor substrate 1, and by doing the like. In a surface of the n⁺ type epitaxial layer 2, p type channel regions 4 are provided. The plurality of channel regions 4 are provided in the surface of the epitaxial layer 2 by ion implantation and diffusion. Note that a low-resistance layer 1 may be formed by impurity diffusion in the semiconductor substrate 2.

A gate oxide film 11 is provided on the surface of the n⁻ type epitaxial layer 2, and the gate electrode 13 (a gate length Lg) is disposed on the gate oxide film 11. On the gate electrode 13, the interlayer insulating film 16 is provided. The gate electrode 13 is covered with the gate oxide film 11 and the interlayer insulating film 16 on a periphery thereof.

As shown in FIG. 1A, the gate electrode 13 configuring one cell is partially divided by the separation hole 12 having a separation width L_{KT}. Specifically, the gate electrode 13 has a stripe shape (both ends are connected) having a slit in which the separation hole 12 is provided in a center thereof. Alternatively, the gate electrode 13 has a concave shape in which the separation hole 12 reaches one end of the gate electrode 13. Moreover, although not shown in the drawing, the gate electrode 13 may have a stripe shape in which the gate electrode 13 is completely separated by the separation hole 12 and the separation hole 12 reaches the both ends of the gate electrode 13. Note that the gate electrodes 13 are bundled together at least outside a MOSFET element region in which the plurality of cells described above are disposed. The separation width L_{KT} is, for example, 0.6 μm. Each of two divided gate electrodes 13a and 13b has an equal gate length Lgd. Moreover, the two divided gate electrodes 13a and 13b as well as the separation hole 12 are covered with the one interlayer insulating film 16. The gate electrode 13 is disposed, for example, in a planar pattern, so as to have a stripe shape having a slit (the both ends are connected), a concave shape or a stripe shape. In either case, the channel regions 4 are disposed in a stripe shape on both sides of the gate electrode 13.

The source region 15 is a high-concentration n type impurity region provided in the surface of the channel region 4, and is disposed below a part of the gate electrode 13 and outside thereof. In the surface of the channel region 4 between the source regions 15, a high-concentration p type body region 17 is provided. The source regions 15 and the body region 17 are in contact with a source electrode 18 through a contact hole CH between the interlayer insulating films 16.

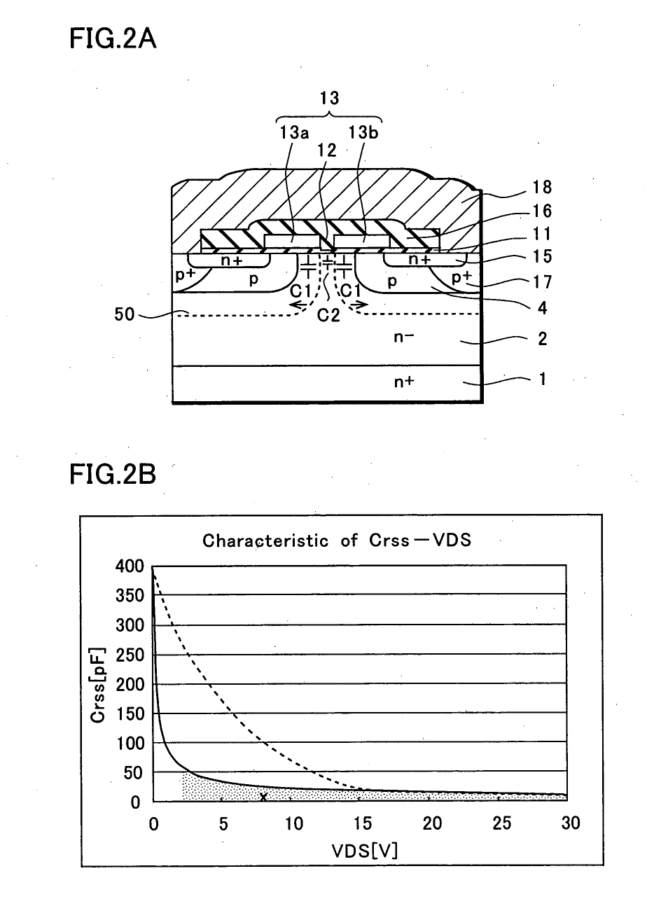

FIGS. 2A and 2B are views showing the foregoing MOSFET in a state where drain-source voltage VDS is low. FIG. 2A is a cross-sectional view, and FIG. 2B is a characteristic graph showing a relationship between feedback capacitance Crss and the drain-source voltage VDS.

When the drain-source voltage VDS is applied, depletion layers 50 are extended from the channel regions 4 and are pinched off below the center of the gate electrode 13. Thereafter, as shown in FIG. 2A, when the drain-source voltage VDS is decreased, the depletion layers 50 extending from the channel regions 4 are narrowed in width.

In this embodiment, the separation hole 12 is formed in the center of the gate electrode 13. Specifically, even if the depletion layers 50 are narrowed in width, only a minute gate-drain capacitance Cgd (the feedback capacitance Crss) is generated between the divided gate electrodes 13a and 13b.

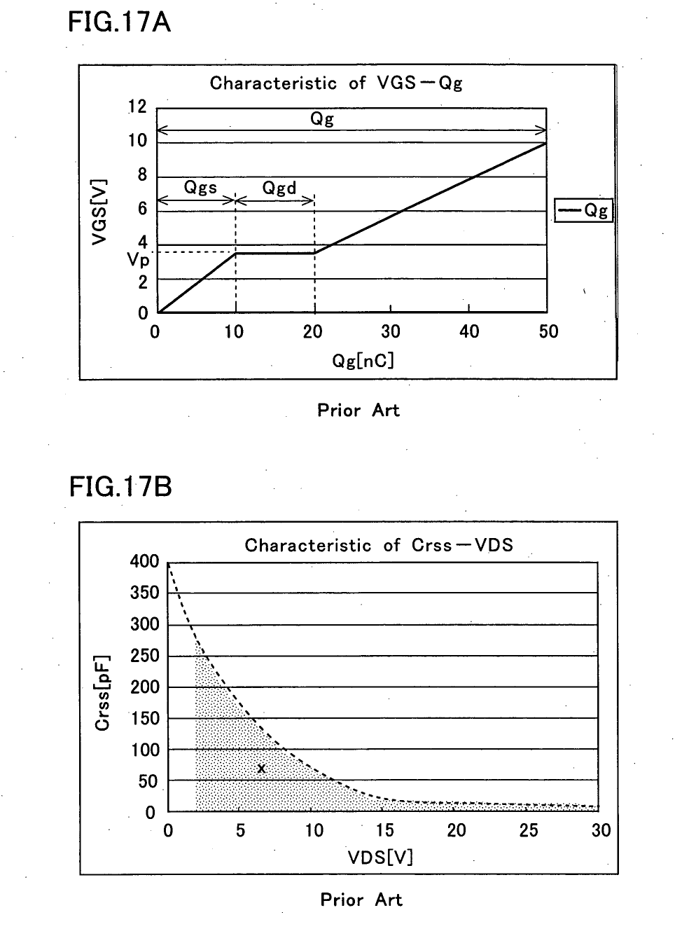

In FIG. 2B, characteristics of this embodiment are indicated by a solid line, and characteristics shown in FIG. 17B are indicated by a broken line.

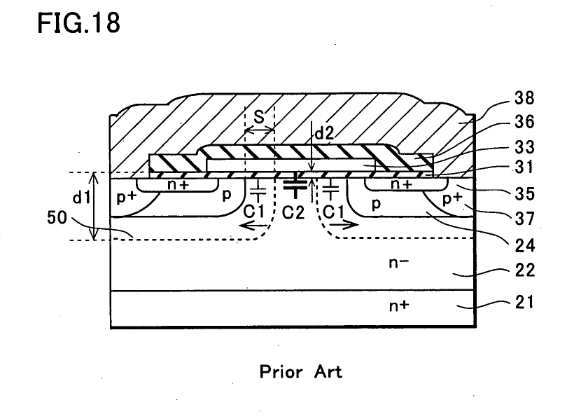

The gate oxide film is a very thin insulating film. Specifically, as in the case of a conventional structure (FIG. 18), when the depletion layers 50 is not generated below the gate electrode and there is only a gate oxide film 31 capacitance C2. Therefore, feedback capacitance Crss is increased. This is also clear from the characteristic graph indicated by the broken line in FIG. 2B. Specifically, when the drain-source voltage VDS falls below a predetermined value (for example, 10 V), the feedback capacitance Crss (the gate-drain capacitance Cgd) is drastically increased.

Meanwhile, in this embodiment, although the gate oxide film capacitance C2 around the center of the gate electrode 13 is generated by the divided gate electrodes 13a and 13b on the both sides, the capacitance is minute. Specifically, it is possible to reduce the drain-source voltage VDS of a limit at which the feedback capacitance Crss is increased. Therefore, as indicated by the solid line, the conventional characteristics can be shifted to the side where the drain-source voltage VDS is low.

Therefore, an integration value of a region x can be reduced. The integration value of the region x is charge Qgd accumulated between the gate and the drain when the MOSFET is in an ON state (when the drain-source voltage VDS is low) (see FIGS. 17A and 17B). At the time of switching, the MOSFET is turned off once the charge Qgd is released. Thus, the smaller the gate-drain charge Qgd, which is the integration value of the region x, the better the high-frequency switching characteristics.

According to this embodiment, although it is inevitable that the feedback capacitance Crss is increased along with a decrease in the drain-source voltage VDS, the integration value of the region x can be reduced compared with the conventional structure. Therefore, this embodiment is very advantageous for high-frequency switching.

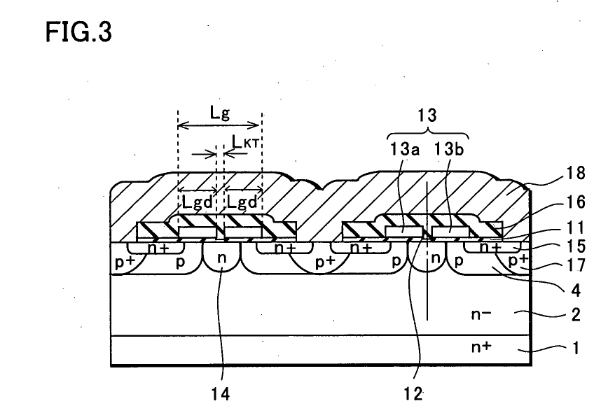

FIG. 3 shows a second embodiment of the present invention. In the second embodiment, an n type impurity region 14 is provided in a surface of an n⁻ type epitaxial layer 2 below a gate electrode 13.

The n type impurity region 14 is provided between each adjacent two of channel regions 4. A depth of the n type impurity region 14 is equal to, or less than, a depth of the channel region 4. Moreover, an impurity concentration of the n type impurity region 14 is about 1×10¹⁷ cm⁻³.

Divided gate electrodes 13a and 13b are disposed symmetrically to a center line of the n type impurity region 14. Specifically, a separation hole 12 is provided above the n type impurity region 14, and a center line of the separation hole 12 and the center line of the n type impurity region 14 approximately coincide with each other as indicated by alternate long and short dashed lines. Since the second embodiment is the same as the first embodiment except for the above, description thereof will be omitted.

As described above, the n type impurity region 14 having a concentration higher than that of the n⁻ type epitaxial layer 2 is provided in the surface of the n⁻ type epitaxial layer 2 below the center of the gate electrode 13. Thus, it is possible to reduce a resistance value in a portion below the gate electrode 13 to be a current path. Therefore, it is possible to contribute to reduction in an on-resistance Ron.

As described later, the n type impurity region 14 can be formed only in a desired region (below the center of the gate electrode 13) by ion implantation from the separation hole 12. Therefore, the channel region 4 and the n type impurity region 14 can be designed independently of each other. Specifically, it is possible to reduce the on-resistance Ron without affecting pinch-off voltage Vp.

Note that, in FIG. 3, the n type impurity region 14 and the channel regions 4 are in contact with each other. However, those regions do not have to be in contact with each other.

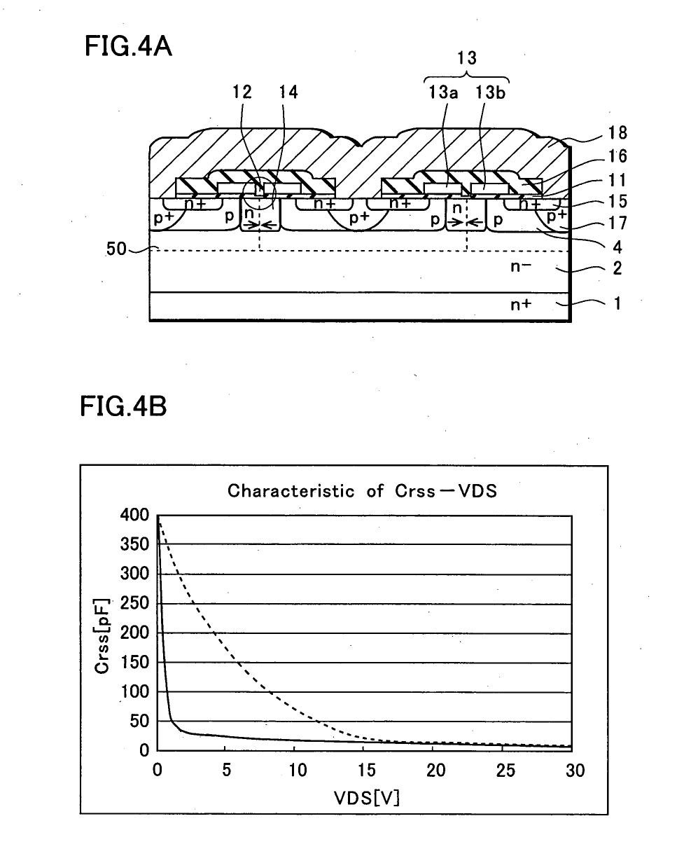

FIGS. 4A and 4B show a third embodiment of the present invention. FIG. 4A is a cross-sectional view, and FIG. 4B is a characteristic graph, of the third embodiment.

As shown in FIG. 4A, in the third embodiment, an n type impurity region 14 and channel regions 4 have approximately the same depth, and junction surfaces therebetween are vertically formed. In order to obtain such a structure, a separation width L_{KT} of a separation hole 12, an impurity concentration of an n⁻ type epitaxial layer 2, a gate length Lg of a gate electrode 13, and impurity concentrations of the n type impurity region 14 and the channel regions 4 are appropriately selected.

Moreover, as in the case of the second embodiment, ion implantation can be performed from the separation hole 12 which equally divides the gate electrode 13. Therefore, the n type impurity region 14 can be formed in a self-aligning manner below a center of the gate electrode 13. Moreover, the n type impurity region 14 can be formed accurately below the center of the gate electrode 13. Thus, it is possible to suppress a variation in extension of depletion layers.

Furthermore, since the n type impurity region 14 is formed by ion implantation from the separation hole 12, the impurity concentrations of the channel regions 4 and the n type impurity region 14 can be individually selected. Therefore, the n type impurity region 14 having a concentration higher than that of the n⁻ type epitaxial layer 2 can be formed while maintaining the impurity concentration of the channel regions 4 at a desired value.

FIG. 4B is a characteristic graph showing a relationship between feedback capacitance Crss and drain-source voltage VDS, in the foregoing structure (a solid line) and the conventional structure (a broken line) shown in FIGS. 17A and 17B.

As described in FIG. 4B, even if the drain-source voltage VDS is decreased, low feedback capacitance Crss can be maintained. Therefore, this embodiment is more advantageous for high-frequency switching characteristics.

Moreover, no curvature is generated in a depletion layers 50, and the depletion layers 50 are extended evenly in a direction perpendicular to the substrate (see FIG. 4A). Thus, the drain-source voltage VDS (withstand voltage) in an OFF state can also be improved.

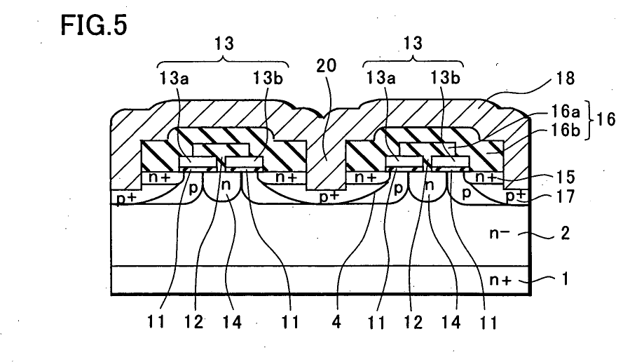

FIG. 5 shows a fourth embodiment of the present invention.

The fourth embodiment includes a solid phase diffusion source 16a which covers a separation hole 12, and a trench 20 provided between source regions 15. Although a manufacturing method will be described later, the solid phase diffusion source 16a is a high-concentration PSG (Phosphorus Silicate Glass) film, and causes impurities in an n type impurity region 14 to undergo solid phase diffusion. The solid phase diffusion source 16a is integrated with a PSG film 16b, which covers a gate electrode 13 on a periphery, to form an interlayer insulating film 16.

The trench 20 is provided between each adjacent two of the source regions 15 in one channel region 4, and is deeper than the source regions 15 and shallower than a body region 17. The source region 15, which is exposed to a part of a side face of the trench 20, and the body region 17, which is exposed to a bottom of the trench 20, are in contact with a source electrode 18. Since constituent components other than those described above are the same as those of the second embodiment, description thereof will be omitted. According to the fourth embodiment, the number of masks can be reduced in the manufacturing method to be described later.

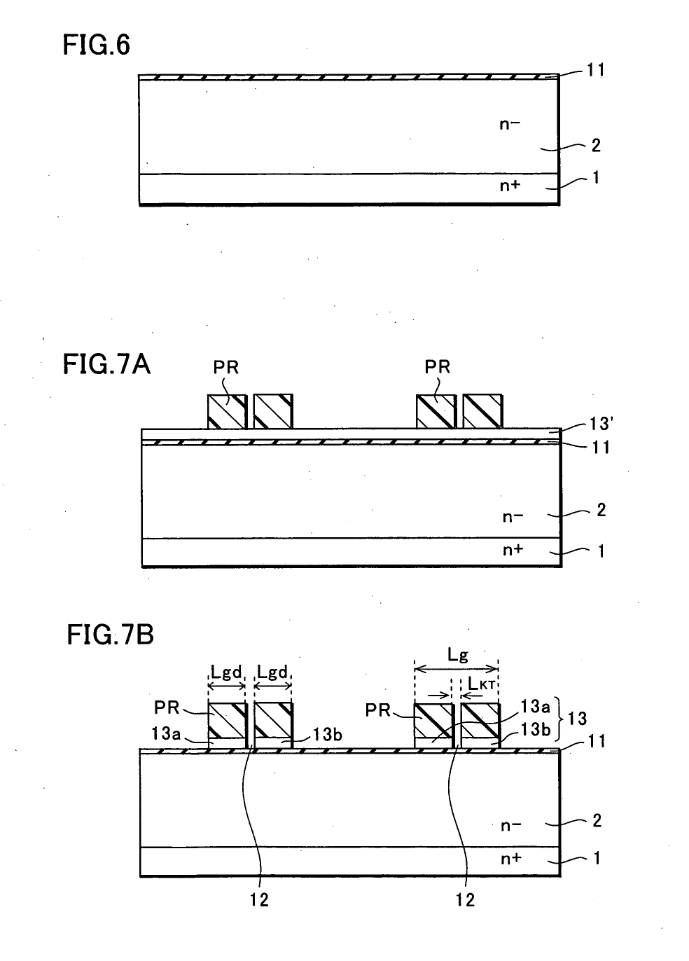

With reference to FIGS. 6 to 15, description will be given of a method of manufacturing an insulated gate field effect transistor of these embodiments. First, with reference to FIGS. 6 to 11, the method will be described by taking the MOSFET shown in FIG. 3 (the second embodiment) as an example.

First Step (see FIG. 6): a step of superposing a one conductivity type semiconductor layer on a one conductivity type semiconductor substrate, and forming an insulating film on a surface of the one conductivity type semiconductor layer.

A drain region is formed by superposing an n⁻ type epitaxial layer 2 on an n⁺ type silicon semiconductor substrate 1, and by doing the like. The entire surface is thermally oxidized (about 1000 degrees Centigrade) to form a gate oxide film 11 having a film thickness depending on a threshold voltage.

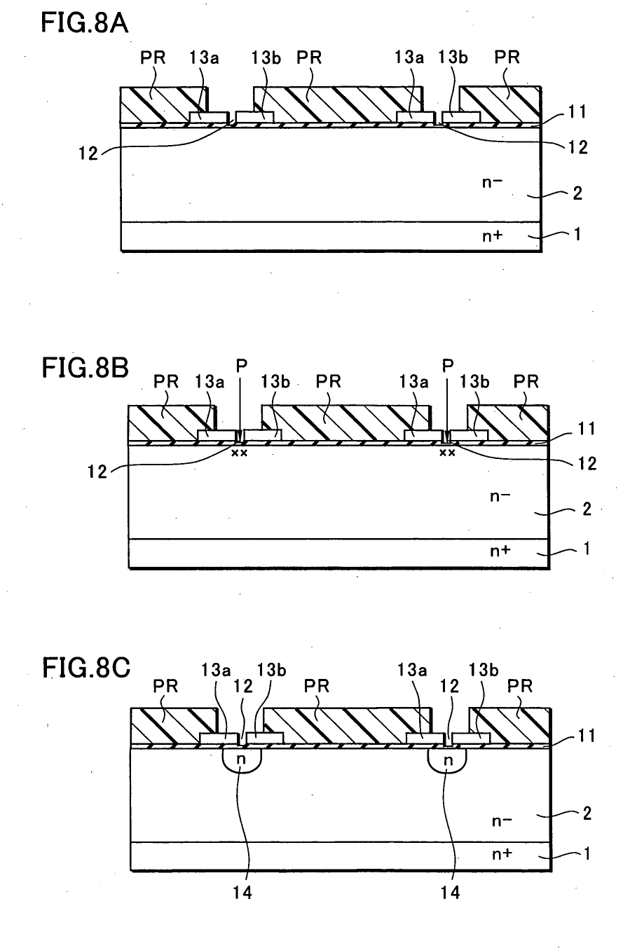

Second Step (see FIGS. 7A to 8C): a step of forming a gate electrode, at least part of which is divided by a separation hole, on the insulating film.

A non-doped polysilicon layer 13′ is deposited on the entire surface, and phosphorus (P), for example, is implanted in the polysilicon layer 13′ and diffused in high concentration to achieve a high conductivity. A resist film PR is formed, and a mask is formed in a pattern which causes a gate electrode formation region to be masked and a separation hole formation region to be exposed (FIG. 7A).

By using the resist film PR as a mask, dry etching is performed to form a gate electrode 13 having a gate length Lg. At the same time, a separation hole 12 is formed in a center portion of at least a part of the gate electrode 13. Specifically, by the separation hole 12 provided in at least a part of the gate electrode 13, two divided gate electrodes 13a and 13b having the same gate length Lgd are formed. One cell of the MOSFET is configured with the two divided gate electrodes 13a and 13b (FIG. 7B).

A width (a separation width L_{KT}) of the separation hole 12 is, for example, 0.6 μm. Note that the gate electrode 13 may be formed by depositing the polysilicon layer 13′ doped with impurities on the entire surface and patterning the polysilicon layer 13′.

By forming the separation hole 12 in the center of the gate electrode 13, an increase in feedback capacitance Crss can be avoided, even if drain-source voltage VDS is decreased and a width of a depletion layer 50 is narrowed.

Next, a one conductivity type impurity region having a concentration higher than that of the n⁻ type epitaxial layer 2 is formed below the gate electrode.

A resist film PR is formed on the entire surface and patterned so as to expose at least the separation hole 12. Thereafter, the gate oxide film 11 exposed from the separation hole 12 is etched for film thickness control. The gate oxide film 11 in the separation hole 12 after etching has a film thickness of, for example, 250 Å (FIG. 8A).

Thereafter, by using the resist film PR as a mask, ions of an n type impurity (for example, phosphorus: P) are implanted. As ion implantation conditions, for example, acceleration energy of 120 KeV and a dose of 2×10¹³ cm⁻² are adopted. The n type impurities are implanted into the surface of the n⁻ type epitaxial layer 2 through the separation hole 12 (FIG. 8B).

Subsequently, heat treatment (at 1150 degrees Centigrade for 180 minutes) is performed to diffuse the impurities. Thus, an n type impurity region 14 having an impurity concentration of about 1×10¹⁷ cm⁻³ is formed (FIG. 8C).

Because the ions of the impurity are implanted through the separation hole 12, fine mask alignment accuracy for forming the resist film PR is not required. Specifically, the n type impurities can be implanted by using the divided gate electrodes 13a and 13b as a mask. Therefore, the mask alignment accuracy is improved, and the n type impurity region 14 can be formed in a self-aligning manner in the center of one gate electrode 13.

It is also conceivable that the n type impurity region 14 is formed by ion implantation and diffusion in the entire surface before the gate electrode 13 is formed. However, if the high-concentration n type impurities are implanted into the entire surface, the impurity concentration of the channel region, which is a p type impurity region, is reduced. Meanwhile, if the impurity concentration of the channel region is increased in consideration of the concentration of the n type impurities, it becomes difficult to control pinch-off voltage Vp. Moreover, lateral diffusion of the channel region narrows a space between the channel regions. Thus, there is also a problem that channels are shortened.

However, according to this embodiment, the n type impurity region 14 can be formed in the self-aligning manner. Moreover, desired impurity concentrations can be selected for the n type impurity region 14 and a channel region to be formed later, respectively.

Specifically, it is possible to form the n type impurity region 14 which sufficiently reduces a resistance value in a portion below the gate electrode 13 without affecting the channel region. Therefore, the channel regions can be accurately formed. Thus, it is possible to stabilize characteristics of the pinch-off voltage Vp, the drain-source voltage VDS and a saturation drain current I_{DSS}. Note that, in the case of the first embodiment, it suffices that the n type impurity region 14 shown in FIG. 8C is not formed in this step.

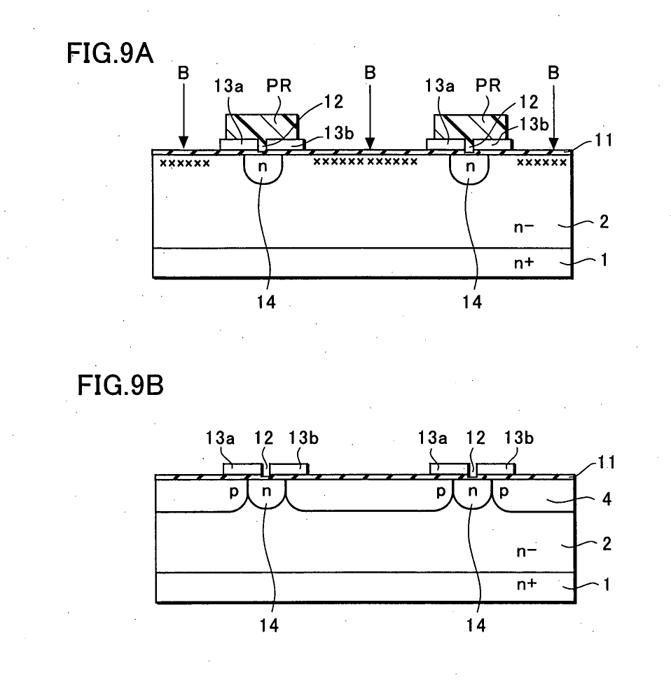

Third Step (see FIGS. 9A and 9B): a step of forming a plurality of opposite conductivity type channel regions in the surface of the semiconductor layer adjacent to the gate electrode.

A resist film PR is formed again, and the resist film PR which covers at least the separation hole 12 is left. Thereafter, ions of a p type impurity (for example, boron: B) are implanted into the surface of the n⁻ type epitaxial layer 2 between each adjacent two of the gate electrodes 13. As ion implantation conditions, for example, acceleration energy of 80 KeV and a dose of 2×10¹³ cm⁻² are adopted (FIG. 9A).

Thereafter, the resist film PR is removed, and heat treatment (at 1150 degrees Centigrade for 180 minutes) is performed to diffuse the p type impurities and form the plurality of a channel regions 4 (FIG. 9B). Accordingly, the channel regions 4 are positioned on both sides of the n type impurity region 14. Note that, although the n type impurity region 14 and the channel regions 4 are in contact with each other in FIG. 9B, those regions do not have to be in contact with each other.

As described above, the n type impurity region 14 is formed by ion implantation through the separation hole 12. Thus, the impurity concentrations of the channel region 4 and the n type impurity region 14 can be individually selected. Therefore, the high-concentration n type impurity region 14 can be formed while maintaining the impurity concentration of the channel region 4 at a desired value.

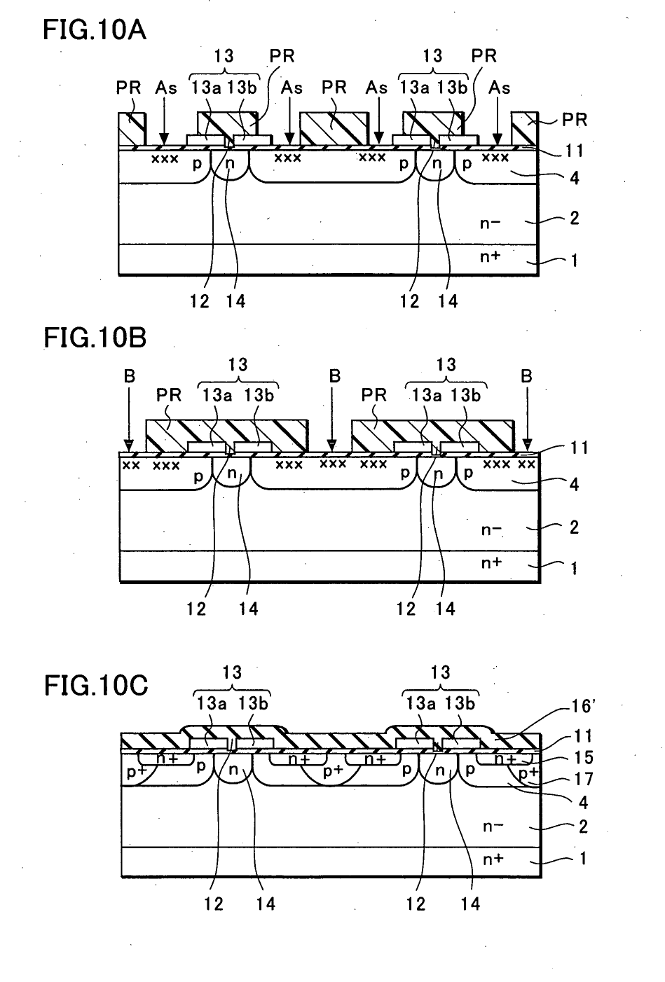

Fourth Step (see FIGS. 10A to 10C): a step of forming a one conductivity type source region and an opposite conductivity type body region in a surface of the channel region.

A mask in which a part of the channel region 4 is exposed is formed by use of a new resist film PR. Thereafter, ions of an n type impurity (for example, arsenic: As) are implanted. Acceleration energy is about 140 KeV, and a dose is about 5×10¹⁵ cm⁻² (FIG. 10A). Moreover, a mask in which the other part of the channel region 4 is exposed is formed, and ions of a p type impurity (for example, boron: B) are implanted. Acceleration energy is about 80 KeV, and a dose is about 2×10⁵ cm⁻² (FIG. 10B).

Thereafter, by use of a CVD method, an insulating film 16′, such as PSG, to be an interlayer insulating film is deposited on the entire surface. By heat treatment (below 1000 degrees Centigrade for about 60 minutes) during the deposition, the n type impurities are diffused. Thus, in the surface of the channel region 4, a source region 15 adjacent to the gate electrode 13 with the gate oxide film 11 interposed in between is formed. At the same time, the p type impurities are diffused to form a body region 17 in the surface of the channel region 4 between the source regions 15 (FIG. 10C). Note that, for the source region 15 and the body region 17, the order of implanting the impurities may be reversed.

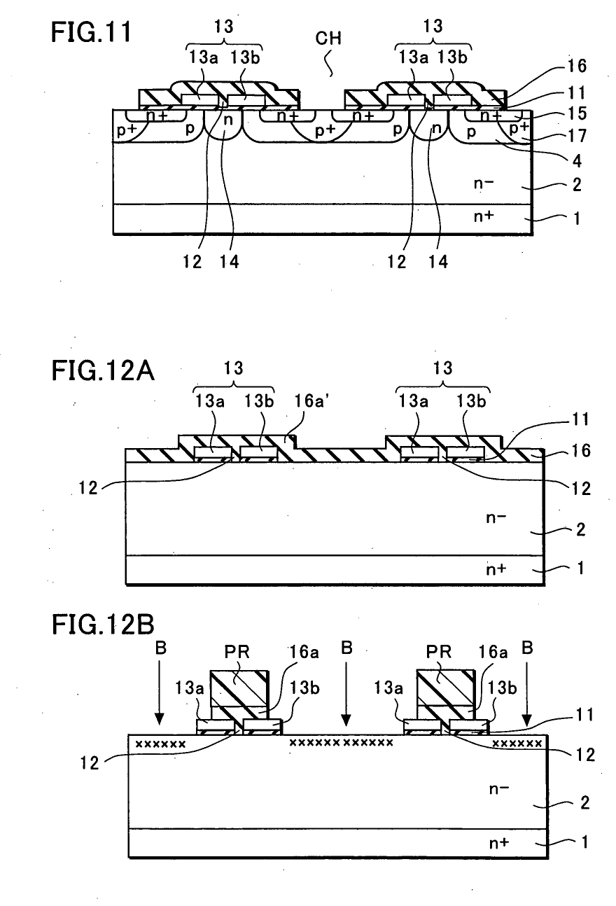

Fifth Step (see FIG. 11): a step of forming an another insulating film which covers the separation hole and the gate electrode.

By using a new resist film (not shown) as a mask, the insulating film 16′ is etched, the interlayer insulating film 16 is left, and a contact hole CH is formed. The interlayer insulating film 16 integrally covers the separation hole 12 and the two divided gate electrodes 13a and 13b above the n type impurity region 14.

Thereafter, a barrier metal layer (not shown) is formed on the entire surface, and aluminum alloy is sputtered in a film thickness of about 20000 to 50000 Å. Subsequently, alloying heat treatment is performed to form a source electrode 18 patterned into a desired shape. Thus, a final structure shown in FIG. 3 is obtained.

Note that, in the second and third steps, the n type impurity region 14 and the channel regions 4 may be formed in such a manner that impurity implantation for the n type impurity region 14 and impurity implantation for the channel regions 4 are consecutively performed and the impurities are diffused at the same time in one heat treatment step.

As for a manufacturing method in the third embodiment, the separation width L_{KT} of the separation hole 12, the gate length Lg of the gate electrode 13 and the impurity concentrations of the n type impurity region 14 and the channel region 4 are appropriately selected in the second and third steps in the manufacturing method in the second embodiment. Moreover, the impurity concentration of the n⁻ type epitaxial layer 2 is also selected in consideration of those described above. Thus, an n type impurity region 14 and the channel regions 4 can have approximately the same depth, and junction surfaces therebetween can be vertically formed.

Next, a manufacturing method in the fourth embodiment will be described. Note that, as to the same steps as those of the second embodiment, description will be omitted.

First and Second Steps (see FIGS. 6 to 7B): a step of superposing a one conductivity type semiconductor layer on a one conductivity type semiconductor substrate, and forming a first insulating film on a surface of the one conductivity type semiconductor layer; and a step of forming a gate electrode, at least part of which is equally divided by a separation hole, on the first insulating film.

As in the case of the manufacturing method of the second embodiment, a drain region is formed by superposing an n⁻ type epitaxial layer 2 on an n⁺ type silicon semiconductor substrate 1, and by doing the like. Moreover, a gate oxide film 11 is formed on the surface. Subsequently, once a polysilicon layer 13′ is deposited, divided gate electrodes 13a and 13b (a gate electrode 13), which are divided by a separation hole 12, are formed on the gate oxide film 11.

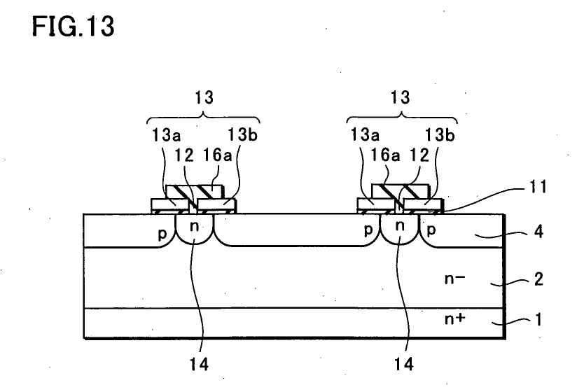

Third Step (see FIGS. 12A to 13): a step of covering the separation hole with a second insulating film containing one conductivity type impurities, forming a plurality of opposite conductivity type channel regions in the surface of the semiconductor layer adjacent to the gate electrode, and forming a one conductivity type impurity region below the gate electrode, the impurity region having an impurity concentration higher than that of the semiconductor layer.

First, by using the gate electrode 13 as a mask, the gate oxide film 11 is removed. Next, a PSG film 16a′ containing high-concentration phosphorus (P) is formed on the entire surface. The PSG film 16a′ serves as a solid phase diffusion source. Thus, the PSG film 16a′ has an impurity concentration of about 1×10¹⁷ cm⁻³ at the time of diffusion, and has a film thickness of about 5000 Å. The separation hole 12 is covered with the PSG film 16a′ (FIG. 12A).

Thereafter, a mask made of a resist film PR is provided, and the PSG film 16a′ is patterned. Thus, a solid phase diffusion source 16a is formed, which covers at least the separation hole 12 and which remains on divided the gate electrodes 13a and 13b. While leaving the resist film PR as it is, ions of a p type impurity (for example, boron: B) are implanted into the entire surface. As ion implantation conditions, for example, acceleration energy of 80 KeV and a dose of 2×10¹³ cm⁻² are adopted (FIG. 12B).

Next, as shown in FIG. 13, the resist film PR is removed, and heat treatment (at 1150 degrees Centigrade for 180 minutes) is performed to diffuse n type impurities into the surface of the n⁻ type epitaxial layer 2 from the solid phase diffusion source 16a. Thus, an n type impurity region 14 (impurity concentration of about 1×10¹⁷ cm⁻³) is formed. Accordingly, the n type impurities can be diffused in a self-aligning manner in the center of one gate electrode 13.

At the same time, a plurality of channel regions 4 are formed by diffusing p type impurities. The channel regions 4 are positioned on both sides of the n type impurity region 14. Note that, although the n type impurity region 14 and the channel regions 4 are in contact with each other in FIG. 13, those regions do not have to be in contact with each other.

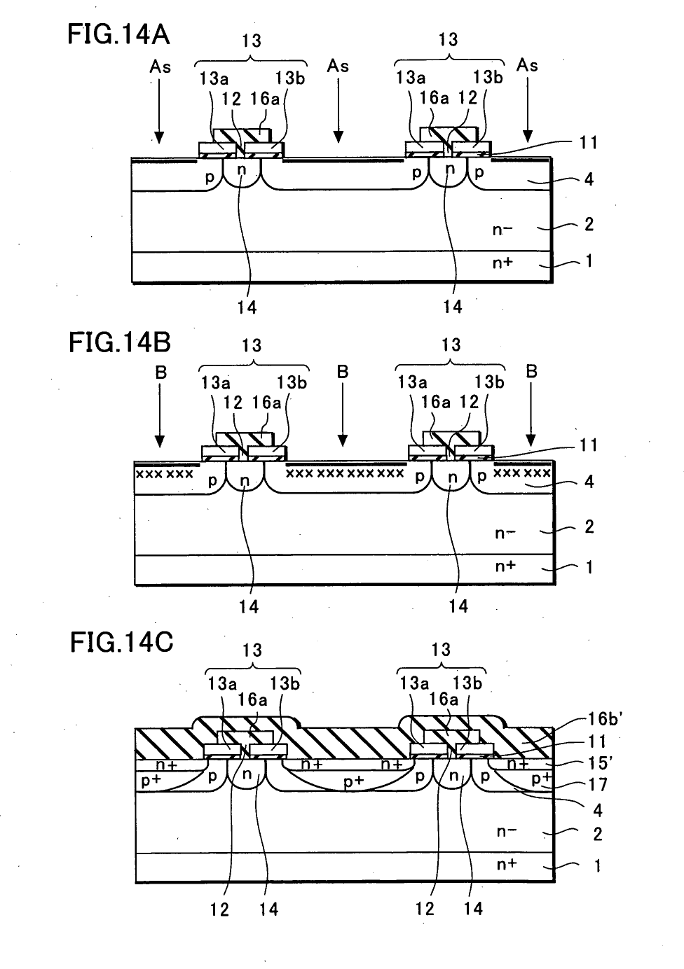

Fourth Step (see FIGS. 14A to 14C): a step of forming a one conductivity type source region and an opposite conductivity type body region in a surface of the channel region.

Ions of an n type impurity (for example, arsenic: As) are implanted into the entire surface. Acceleration energy is about 140 KeV, and a dose is about 5×10¹⁵ cm⁻² (FIG. 14A).

Subsequently, ions of a p type impurity (for example, boron: B) are implanted into the entire surface. In this event, the ion implantation is performed so as to have a peak concentration of the p type impurities deeper than a peak concentration of the n type impurities (FIG. 14B). Note that the order of implanting the impurities described above may be reversed.

Thereafter, by use of a CVD method, an insulating film 16b′ such as PSG is deposited on the entire surface. By heat treatment (below 1000 degrees Centigrade for about 60 minutes) during the deposition, the n type impurities and the p type impurities are diffused. Thus, in the surface of the channel region 4 between the gate electrodes 13, an n⁺ type impurity region 15′ is formed. At the same time, a body region 17 is formed under the n⁺ type impurity region 15′ (FIG. 14C).

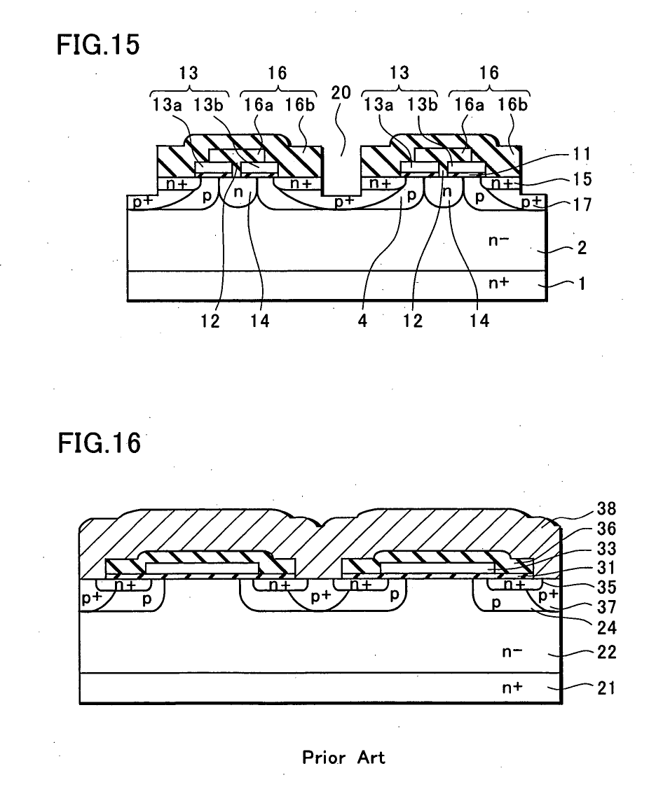

Fifth Step (see FIG. 15): a step of forming a third insulating film which covers the separation hole and the gate electrode.

By using a new resist film (not shown) as a mask, the insulating film 16b′ is etched and the surface of the n⁻ type epitaxial layer 2 is also etched. Thus, a trench 20 is formed between each adjacent two of the gate electrodes 13. The trench 20 is formed so as to be deeper than the n⁺ type impurity region 15′ and so as not to reach the n⁻ type epitaxial layer 2. Thus, the n⁺ type impurity region 15′ is divided to form source regions 15 adjacent to the gate electrode 13 and the insulating film 16b′ is divided to form an insulating film 16b. Moreover, the source regions 15 are exposed to side faces of the trench 20, and the body region 17 is exposed to a bottom of the trench 20.

The insulating film 16b and the solid phase diffusion source 16a become an interlayer insulating film 16 which integrally covers the two divided gate electrodes 13a and 13b and the separation hole 12 above the n type impurity region 14.

Thereafter, a barrier metal layer (not shown) is formed on the entire surface, and aluminum alloy is sputtered in a film thickness of about 20000 to 50000 Å. Subsequently, alloying heat treatment is performed to form a source electrode 18 patterned into a desired shape. The source electrode 18 are in contact with the source regions 15 and the body region 17, which are exposed in the trench 20. Thus, a final structure shown in FIG. 5 is obtained.

The description was given above by taking the n-channel MOSFET as an example in the embodiments of the present invention. However, the present invention is similarly applicable to a p-channel MOSFET having a conductivity type reversed. Furthermore, the present invention is also similarly applicable to an IGBT(Insulated Gate Bipolar Transistor) having an opposite conductivity type semiconductor layer disposed below a one conductivity type semiconductor substrate 1.

First, according to the present invention, one gate electrode is equally divided by a separation hole. A depletion layer extending from a channel region is pinched off below a center of the gate electrode. In this embodiment, the gate electrode above a pinch-off region is removed. Thus, gate-drain capacitance Cgd (feedback capacitance Crss) in an ON state where the depletion layer starts to retreat (when the drain-source voltage VDS decreases) can be significantly reduced. Consequently, high-frequency characteristics can be improved.

Moreover, even if the drain-source voltage VDS, which is low enough to cause the depletion layer to start to retreat, is applied to the insulated gate field effect transistor of this embodiment, the feedback capacitance Crss is increased only slightly. Specifically, the drain-source voltage VDS of a limit, at which the feedback capacitance Crss is drastically increased, can be shifted to low voltage. It is inevitable that the feedback capacitance Crss is increased along with a decrease in the drain-source voltage VDS. However, according to this embodiment, an integration value of a region x can be reduced. Thus, the high-frequency characteristics can be improved.

Second, an n type impurity region having a concentration higher than that of an n⁻ type epitaxial layer is provided below a separation hole. The n type impurity region can reduce a resistance in a portion below the gate electrode to be a current path. Thus, an on-resistance can be reduced.

Third, the n type impurity region can be formed in a self-aligning manner by implantation of impurities from the separation hole and diffusion thereof. Specifically, it is possible to provide a method of manufacturing an insulated gate field effect transistor which reduces the on-resistance without adding a mask for forming the n type impurity region.

Fourth, the n type impurity region is formed by ion implantation from the separation hole. Thus, impurity concentrations of the channel region and the n type impurity region can be individually selected. Therefore, the high-concentration n type impurity region can be formed while maintaining the impurity concentration of the channel region at a desired value. Fifth, the separation hole is covered with a high-concentration PSG film, and impurities are diffused from the high-concentration PSG film. Moreover, once ions of an impurity, which become a source region and a body region, are implanted into the entire surface, a trench is formed to divide the source region. Thus, the number of masks can be reduced.

What is claimed is:

1. An insulated gate field effect transistor comprising:
a semiconductor substrate of a first general conductivity type;
a semiconductor layer of the first general conductivity type disposed on the semiconductor substrate so as to provide a drain region;
a first channel region, a second channel region, a third channel region and a fourth channel region that are of a second general conductivity type and formed in the semiconductor layer;
a first gate electrode disposed on the first and second channel regions and having a separation separating a first part of the first gate electrode from a second part of the first gate electrode;
a second gate electrode disposed on the third and fourth channel regions and having a separation separating a first part of the second gate electrode from a second part of the second gate electrode;
a body region of the second general conductivity type formed in the semiconductor layer and connecting the second and third channel regions; and
a source region of the first general conductivity type formed in each of the channel regions.

2. The insulated gate field effect transistor of claim 1, further comprising an insulating film covering the first and second gate electrodes and a source electrode disposed on the insulating film and in contact with the source regions and the body region through a via hole formed in the insulating film.

3. The insulated gate field effect transistor of claim 1, further comprising an impurity region of the first general conductivity type formed in the semiconductor layer and under the separation of the first gate electrode, wherein an impurity concentration of the impurity region is higher than an impurity concentration of the semiconductor layer.

4. The insulated gate field effect transistor of claim 3, wherein a width of the first part of the first gate electrode is equal to a width of the second part of the first gate electrode, and a center of the separation of the first gate electrode is located at a center of the impurity region.

5. The insulated gate field effect transistor of claim 2, wherein the insulating film fills the separations of the first and second gate electrodes.

6. The insulated gate field effect transistor of claim 1, further comprising an insulating film covering the first gate electrode and an impurity region of the first general conductivity type formed in the semiconductor layer and under the separation of the first gate electrode, wherein the insulating film is in direct contact with the impurity region, and part of the insulating film in contact with the impurity region contains impurity ions of the first general conductivity type.

7. The insulated gate field effect transistor of claim 2, further comprising a trench formed in the body region and filled with the source electrode.

8. A method of manufacturing an insulated gate field effect transistor, comprising:
providing a device intermediate comprising a semiconductor substrate of a first general conductivity type, a semiconductor layer of the first general conductivity type disposed on the semiconductor substrate and an insulating film disposed on the semiconductor layer;
forming a first gate electrode on the insulating film having a separation so that the insulating film is exposed at a bottom of the separation of the first gate electrode;
forming a second gate electrode on the insulating film having a separation so that the insulating film is exposed at a bottom of the separation of the second gate electrode;
forming an impurity region of a second general conductivity type in the semiconductor layer between the first and second gate electrodes;
forming a first source region of the first general conductivity type in the impurity region adjacent the first gate electrode;
forming a second source region of the first general conductivity type in the impurity region adjacent the second gate electrode; and
forming a body region of the second general conductivity type in the impurity region between the first and second source regions.

9. The method of claim 8, further comprising implanting impurity ions of the first general conductivity type through the separations of the first and second gate electrodes into the semiconductor layer.

10. The method of claim 8, further comprising etching the insulating film exposed at the bottom of the separations of the first and second gate electrodes.

11. A method of manufacturing an insulated gate field effect transistor, comprising:
providing a device intermediate comprising a semiconductor substrate of a first general conductivity type, a semiconductor layer of the first general conductivity type disposed on the semiconductor substrate and a first insulating film disposed on the semiconductor layer;
forming a gate electrode on the first insulating film having a separation so that the first insulating film is exposed at a bottom of the separation;
forming a second insulting film on the gate electrode to fill the separation, the second insulating film containing impurity ions of the first general conductivity type;
forming an impurity region of the first general conductivity type under the separation by diffusing the impurity ions from the second insulating film; and
forming a source region of the first general conductivity type in the semiconductor layer adjacent the gate electrode.

12. The method of claim 11, further comprising forming a trench to penetrate the source region.

13. A method of manufacturing an insulated gate field effect transistor, comprising:
providing a device intermediate comprising a semiconductor substrate of a first general conductivity type, a semiconductor layer of the first general conductivity type disposed on the semiconductor substrate and an insulating film disposed on the semiconductor layer;
forming a first gate electrode on the insulating film having a separation so that the insulating film is exposed at a bottom of the separation of the first gate electrode;
forming a second gate electrode on the insulating film having a separation so that the insulating film is exposed at a bottom of the separation of the second gate electrode;
forming an impurity region of a second general conductivity type in the semiconductor layer between the first and second gate electrodes;
forming a first source region of the first general conductivity type in the impurity region adjacent the first gate electrode;
forming a second source region of the first general conductivity type in the impurity region adjacent the second gate electrode; and
forming a trench in the impurity region so that the trench is positioned between the first and second source regions.
